(19) United States
(12) Patent Application Publication
(10) Pub. No.: US 2020/0347490 A1
(43) Pub. Date: Nov. 5, 2020

(54) METAL SURFACE PROTECTIVE LAYER AND PREPARATION METHOD THEREOF

(71) Applicant: CITIC Dicastal CO., LTD., Qinhuangdao (CN)

(72) Inventors: Junfu LI, Qinhuangdao (CN); Zaide Wang, Qinhuangdao (CN); Shengchao Zhang, Qinhuangdao (CN); Peng Han, Qinhuangdao (CN); Shuai Li, Qinhuangdao (CN); Huanming Ma, Qinhuangdao (CN); Mengnan Ma, Qinhuangdao (CN)

(21) Appl. No.: 16/552,152

(22) Filed: Aug. 27, 2019

(30) Foreign Application Priority Data
May 5, 2019 (CN) 201910368740.3

(51) Int. Cl. C23C 14/02; C23C 14/16; C23C 14/35; C23C 14/58; B05D 1/12

(52) U.S. Cl. CPC C23C 14/024; C23C 14/165; B60B 27/00; C23C 14/584; B05D 1/12; C23C 14/352

(57) ABSTRACT

The disclosure provides a metal surface protective layer and a preparation method thereof. The metal surface protective layer comprises an organic medium layer, a metal coating layer and a transparent powder layer from inside to outside, wherein the organic medium layer is formed by spraying organic medium powder onto the surface of metal to be treated, the metal coating layer is formed by performing magnetron sputtering PVD plating on the organic medium layer, the organic medium layer is subjected to surface activation and cleaning treatment before the magnetron sputtering PVD plating, and the transparent powder layer is formed by spraying transparent powder onto the metal coating layer.

### CROSS-REFERENCE TO RELATED APPLICATIONS

This application claims priority to Chinese Patent Application No. 201910368740.3, filed on May 5, 2019, the contents of which are hereby incorporated by reference in its entirety.

### BACKGROUND

In related art, aluminum alloy wheel hubs need to be subjected to surface treatment after processing, so as to form a surface protective layer, which not only makes the aluminum alloy wheel hubs more corrosion-resistant, but also makes the appearance more attractive.

In order to reduce pollution, electroplating, which is currently adopted for the surface treatment of the aluminum alloy wheel hubs, is gradually replaced by magnetron sputtering physical vapor deposition (PVD) plating. A hub surface subjected to magnetron sputtering PVD plating has a metallic luster decoration effect, is beautiful and elegant in appearance, and can generate a stereoscopic effect; moreover, in the whole process of magnetron sputtering, no waste water or waste gas is produced, so environment friendliness is realized.

However, since the surface of a cast aluminum alloy wheel hub is rough after machining, a bright film cannot be formed if the cast aluminum alloy wheel hub is directly coated, and the normal appearance requirement cannot be met. Therefore, a high-gloss organic medium layer needs to be sprayed on the surface of the wheel hub to form a bright and flat surface on the wheel hub, and then coating is performed on the surface, so that a mirror-like hub surface can be obtained. However, due to the poor adhesion between the organic medium layer and a metal coating layer, the metal coating layer falls off easily, which also leads to the fact that magnetron sputtering PVD plating has not been widely popularized in the aluminum alloy wheel hub industry.

### SUMMARY

The disclosure relates to metal surface treatment, in particular to a metal surface protective layer and a preparation method thereof.

The embodiments of the disclosure aim to provide a metal surface protective layer and a preparation method thereof, which can improve the adhesion between an organic medium layer and a metal coating layer.

In a first aspect, the embodiments of the present disclosure provide a metal surface protective layer. The metal surface protective layer comprises an organic medium layer, a metal coating layer and a transparent powder layer from inside to outside, in which the organic medium layer is formed by spraying organic medium powder onto the surface of metal to be treated, the metal coating layer is formed by performing magnetron sputtering PVD plating on the organic medium layer, the organic medium layer is subjected to surface activation and cleaning treatment before the magnetron sputtering PVD plating, and the transparent powder layer is formed by spraying transparent powder onto the metal coating layer.

In one possible embodiment of the first aspect, the surface activation and cleaning treatment is plasma treatment.

In one possible embodiment of the first aspect, the metal protective layer further comprises a passivation layer, the passivation layer is formed by performing zirconium-titanium pretreatment on a substrate surface of the metal to be treated, and the passivation layer is between the substrate surface of the metal to be treated and the organic medium layer.

In one possible embodiment of the first aspect, the organic medium layer is made of epoxy resin, the metal coating layer comprises a first sputtering layer with a target of nickel-chromium alloy and a second sputtering layer with a target of pure chromium, and the transparent powder layer is made of acrylic resin.

In one possible embodiment of the first aspect, the thickness of the metal coating layer is 0.08-0.1 μm, the thickness of the organic medium layer is 120-150 μm, and the thickness of the transparent powder layer is 80-120 μm.

In a second aspect, the embodiments of the present disclosure provide a preparation method of a metal surface protective layer, and the method comprises the following steps:

spraying an organic medium material onto the surface of metal to be treated to form an organic medium layer;

performing surface activation and cleaning treatment on the organic medium layer to improve the activity and cleanliness of the surface of the organic medium layer;

performing magnetron sputtering PVD plating on the organic medium layer subjected to surface activation and cleaning treatment to form a metal coating layer; and

spraying transparent powder onto the metal coating layer to form a transparent powder layer.

In one possible embodiment of the second aspect, the step of performing surface activation and cleaning treatment on the organic medium layer to improve the activity and cleanliness of the surface of the organic medium layer comprises:

performing surface plasma treatment on the organic medium layer.

In one possible embodiment of the second aspect, before spraying the organic medium material onto the metal surface to be treated to form the organic medium layer, the method further comprises:

performing zirconium-titanium pretreatment on a substrate surface of the metal to be treated to form a passivation layer.

In one possible embodiment of the second aspect, the step of performing magnetron sputtering PVD plating on the organic medium layer subjected to surface activation and cleaning treatment to form the metal coating layer comprises:

performing magnetron sputtering PVD plating on the organic medium layer by taking nickel-chromium alloy as a target, to form a first sputtering layer; and

performing magnetron sputtering PVD plating on the first sputtering layer by taking pure chromium as a target, to form a second sputtering layer.

In one possible embodiment of the second aspect, in the step of performing surface plasma treatment on the organic medium layer,

a plate electrode for plasma treatment is made of aluminum alloy, oxygen serves as gas, the working pressure of the gas is 0.003-0.008 torr, and the working power of a device for plasma treatment 1.2-1.5 kW.

The embodiments of the present disclosure provide a metal surface protective layer and a preparation method thereof. The metal surface protective layer comprises an organic medium layer, a metal coating layer and a transparent powder layer from inside to outside, in which the organic medium layer is formed by spraying organic medium powder onto the surface of metal to be treated, the metal coating layer is formed by performing magnetron sputtering PVD plating on the organic medium layer, the organic medium layer is subjected to surface activation and cleaning treatment before the magnetron sputtering PVD plating, and the transparent powder layer is formed by spraying transparent powder onto the metal coating layer. It can be seen that according to the metal surface protective layer and the preparation method thereof, by performing surface activation and cleaning treatment on the organic medium layer, the adhesion between the organic medium layer and the metal coating layer is improved.

Other beneficial effects of the embodiments of the present disclosure will be further explained in the detailed description in conjunction with specific technical solutions.

### BRIEF DESCRIPTION OF THE DRAWINGS

FIG. 1 is a structural diagram of a surface protective layer of an aluminum alloy wheel hub according to Example 1 of the present disclosure;

FIG. 2 is a structural diagram of a metal coating layer in a surface protective layer of an aluminum alloy wheel hub according to Example 1 of the present disclosure; and

FIG. 3 is a flow chart of a preparation method of a surface protective layer of an aluminum alloy wheel hub according to Example 2 of the present disclosure.

### DETAILED DESCRIPTION

It should be noted that in the description of the embodiments of the present disclosure, unless otherwise specified and limited, the term “connection” should be understood broadly, for example, it can be electrical connection or internal communication between two elements, it can be direct connection or indirect connection through a medium, and for a person of ordinary skill in the art, the specific meaning of the above term can be understood according to the specific situation. The terms “first, second, and third” in the embodiments of the present disclosure are only used to distinguish similar objects and do not represent a specific order of the objects. It is understood that the sequence of “first, second, and third” can be interchanged if allowed.

The embodiments of the present disclosure provide a metal surface protective layer. The metal surface protective layer comprises an organic medium layer, a metal coating layer and a transparent powder layer from inside to outside, in which the organic medium layer is formed by spraying organic medium powder onto the surface of metal to be treated, the metal coating layer is formed by performing magnetron sputtering PVD plating on the organic medium layer, the organic medium layer is subjected to surface activation and cleaning treatment before the magnetron sputtering PVD plating, and the transparent powder layer is formed by spraying transparent powder onto the metal coating layer.

Herein, the organic medium layer, also known as a high-gloss organic medium layer, can have a mirror-finishing effect after spraying and curing, which is beneficial to the following magnetron sputtering PVD plating.

According to the metal surface protective layer provided by the embodiments of the disclosure, by performing surface activation and cleaning treatment on the organic medium layer, the adhesion between the organic medium layer and the metal coating layer is improved.

In one embodiment, the surface activation and cleaning treatment is plasma treatment. In the plasma treatment technology, also known as plasma treatment technology, a plasma processor is used to physically and chemically modify a film, UV coating or plastic sheet on the surface of a packaging box, so as to improve the surface activity and clean the surface. It can be understood that the surface activation and cleaning treatment can also be realized in other ways, such as heat treatment of a surface to be activated or cleaned.

In one embodiment, the metal protective layer further comprises a passivation layer, the passivation layer is formed by performing zirconium-titanium pretreatment on a substrate surface of metal to be treated, and the passivation layer is between the substrate surface of the metal to be treated and the organic medium layer. The zirconium-titanium pretreatment is mainly used for removing rust or pollutants on the surface of the metal to be treated without mechanical means and without causing too much pollution, which is the preferred mode.

In one embodiment, the organic medium layer is made of epoxy resin which can bond well with the metal surface and has excellent corrosion resistance, which is the preferred mode.

In one embodiment, the metal coating layer comprises a first sputtering layer with a target of nickel-chromium alloy and a second sputtering layer with a target of pure chromium; in this way, a glossy appearance can be realized, cracks can be avoided, and excellent corrosion resistance and good adhesion can be ensured, which is the preferred mode.

In one embodiment, the transparent powder layer is made of acrylic resin. The acrylic resin can bond well with a coating film, and has excellent aging resistance itself, which is the preferred mode.

In one embodiment, the thickness of the metal coating layer is 0.08-0.1 μm, the thickness of the organic medium layer is 120-150 μm, and the thickness of the transparent powder layer is 80-120 μm. The thickness of each layer is generally determined according to different metal materials and the use environment of the metal materials, and the above thickness values are the preferred mode for one or several products.

The embodiments of the present disclosure further provide a preparation method of a metal surface protective layer, and the method comprises the following steps:

spraying an organic medium material onto the surface of metal to be treated to form an organic medium layer;

performing surface activation and cleaning treatment on the organic medium layer to improve the activity and cleanliness of the surface of the organic medium layer;

performing magnetron sputtering PVD plating on the organic medium layer subjected to surface activation and cleaning treatment to form a metal coating layer;

and spraying transparent powder onto the metal coating layer to form a transparent powder layer.

In one embodiment, the step of performing surface activation and cleaning treatment on the organic medium layer to improve the activity and cleanliness of the surface of the organic medium layer comprises:

performing surface plasma treatment on the organic medium layer.

In one embodiment, before spraying the organic medium material onto the surface of the metal to be treated to form the organic medium layer, the method further comprises:

performing zirconium-titanium pretreatment on a substrate surface of the metal to be treated to form a passivation layer.

In one embodiment, the step of performing magnetron sputtering PVD plating on the organic medium layer subjected to surface activation and cleaning treatment to form the metal coating layer comprises:

performing magnetron sputtering PVD plating on the organic medium layer by taking nickel-chromium alloy as a target, to form a first sputtering layer;

and performing magnetron sputtering PVD plating on the first sputtering layer by taking pure chromium as a target, to form a second sputtering layer.

In one embodiment, in the step of performing surface plasma treatment on the organic medium layer,

a plate electrode for plasma treatment is made of aluminum alloy, oxygen serves as gas, the working pressure of the gas is 0.003-0.008 torr, and the working power of a device for plasma treatment 1.2-1.5 kW. The above parameters for plasma treatment are generally determined according to different metal materials and the use environment of the metal materials. Better parameters can make the adhesion of the organic medium layer higher. The above parameters are the preferred mode for one or several products.

The detailed technical solution of the present disclosure will be described below with reference to the drawings and specific Examples. It should be understood that the attached drawings and Examples are only used to explain the present disclosure, and are not used to limit the present disclosure.

### Example 1

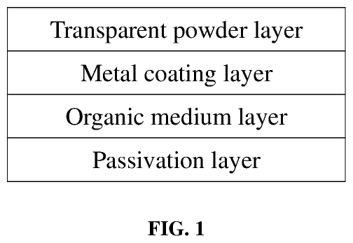

This Example provides a surface protective layer of an aluminum alloy wheel hub, as shown in FIG. 1. The metal surface protective layer comprises a passivation layer, an organic medium layer, a metal coating layer and a transparent powder layer from inside to outside.

The passivation layer is formed by performing zirconium-titanium pretreatment on a substrate surface of metal to be treated, the organic medium layer is formed by spraying organic medium powder onto the surface of metal to be treated, the organic medium powder is epoxy resin powder, the adhesion between epoxy resin and an aluminum alloy substrate is good, and the spraying thickness of the organic medium layer is 120 μm.

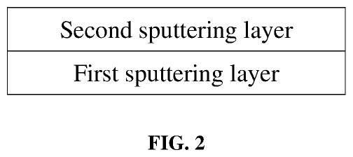

The metal coating layer is formed by performing magnetron sputtering PVD plating on the organic medium layer, as shown in FIG. 2, and the metal coating layer comprises a first sputtering layer with a target of nickel-chromium alloy and a second sputtering layer with a target of pure chromium. The total thickness of the metal coating layer is 0.08 μm, and the thicknesses of the first sputtering layer and the second sputtering layer are the same or close to each other.

The transparent powder layer is formed by spraying transparent powder on the metal coating layer, the transparent powder is acrylic resin powder coating, acrylic resin can bond well with the metal coating layer and has excellent aging resistance, and the thickness of the transparent powder layer is 80 μm.

### Example 2

This Example is the same as Example 1 except for the thicknesses of the organic medium layer, the metal coating layer and the base powder layer. These differences will be described below.

In this Example, the thickness of the organic medium layer is 150 μm.

In this Example, the total thickness of the metal coating layer is 0.1 μm.

In this Example, the thickness of the transparent powder layer is 150 μm.

### Example 3

This Example is the same as Example 1 except for the thicknesses of the organic medium layer, the metal coating layer and the base powder layer. These differences will be described below.

In this Example, the thickness of the organic medium layer is 120 μm.

In this Example, the total thickness of the metal coating layer is 0.1 μm.

In this Example, the thickness of the transparent powder layer is 120 μm.

### Example 4

This Example is the same as Example 1 except for the thicknesses of the organic medium layer, the metal coating layer and the base powder layer. These differences will be described below.

In this Example, the thickness of the organic medium layer is 150 μm.

In this Example, the total thickness of the metal coating layer is 0.08 μm.

In this Example, the thickness of the transparent powder layer is 120 μm.

### Example 5

This Example is the same as Example 1 except for the thicknesses of the organic medium layer, the metal coating layer and the base powder layer. These differences will be described below.

In this Example, the thickness of the organic medium layer is 120 μm.

In this Example, the thickness of the metal coating layer is 0.1 μm.

In this Example, the thickness of the transparent powder layer is 100 μm.

### Example 6

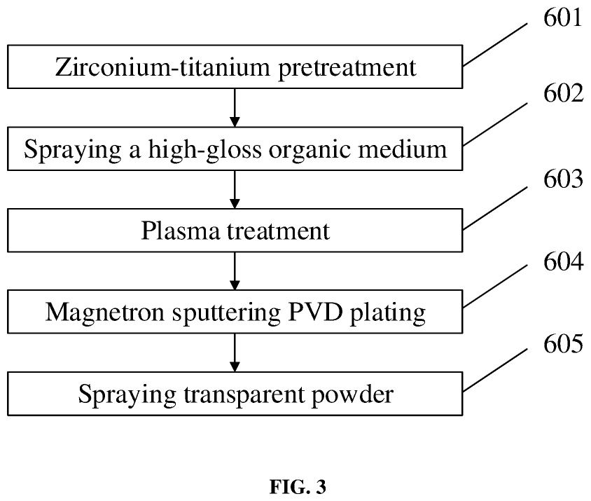

This Example provides a preparation method of a surface protective layer of an aluminum alloy wheel hub, as shown in FIG. 3, and the preparation method comprises the following steps:

Step 601: zirconium-titanium pretreatment. Zirconium-titanium pretreatment is performed on a surface to be treated, namely a rough surface of the aluminum alloy wheel hub. The zirconium-titanium pretreatment at least comprises the following steps: degreasing alkali washing, acid pickling, zirconium-titanium passivation, and blocking;

preferably, the zirconium-titanium pretreatment comprises the following steps: hot water washing, degreasing alkali washing, hot water washing, water washing, acid pickling, pure water washing, pure water washing, zirconium-titanium passivation, pure water washing, blocking, pure water washing, pure water washing and drying;

specifically, the parameters for the zirconium-titanium pretreatment are as follows: the baking temperature of a moisture oven is 110° C., and the baking time is 10 minutes; after treatment, a zirconium-titanium conversion film, namely a passivation layer, is formed, the passivation layer can improve the corrosion resistance of the aluminum alloy wheel hub, and can also improve the bonding force between an aluminum alloy substrate and a high-gloss organic medium layer, meanwhile, the treatment process produces little pollution and is environment-friendly.

Step 602: spraying a high-gloss organic medium. High-gloss organic medium powder is sprayed onto the surface to be treated after zirconium-titanium pretreatment, to form a high-gloss organic medium layer; specifically, the curing temperature of the high-gloss organic medium layer is 200° C., the curing time is 25-35 minutes, the pencil hardness after curing is 2-3 H, the glass transition temperature of a coating is preferably 80-120° C., and the color of the high-gloss organic medium powder is preferably black.

Step 603: plasma treatment. Plasma treatment is performed on the high-gloss organic medium layer. Specifically, plate electrodes in an equipment cavity for plasma treatment are made of rectangular aluminum alloy and are distributed above, beside and below the aluminum alloy wheel hub, to conduct treatment sequentially, so as to ensure uniform treatment at each position. The specific process of treatment is as follows:

Firstly, the pressure in the cavity is pumped to 0.00005 torr (i.e. with a certain vacuum degree) by a molecular pump, then oxygen is introduced into the cavity, and the flow rate of oxygen is 400 sccm; when the pressure in the cavity is stabilized to 0.008 torr, a radio frequency power supply is turned on, at this point, high voltage ionizes oxygen molecules to generate oxygen atoms, oxygen ions and free electrons, and under the action of the electric field, the oxygen ions and free electrons bombard the surface of the aluminum alloy wheel hub at high speeds; impurities on the surface of the aluminum alloy wheel hub are removed, and a new chemical bond is formed on the surface of the aluminum alloy wheel hub, in which the chemical bond is used for bonding with a metal coating, so that the high-gloss organic medium layer and the metal coating layer can bond more firmly;

specifically, during plasma treatment, the surface temperature of the aluminum alloy wheel hub is 80° C., the working power of the plate electrodes in plasma equipment is 1.5 kW, the upper plate electrodes work for 16 seconds, and then the side and lower plate electrodes work for another 16 seconds; at the same time, the aluminum alloy wheel hub itself also rotates during plasma treatment, with a rotation speed of 2 seconds per circle.

Step 604: magnetron sputtering PVD plating. Magnetron sputtering PVD plating is performed on the surface to be treated after plasma treatment to form the metal coating layer, in which the metal coating layer comprises a first sputtering layer and a second sputtering layer from inside to outside, the target of the first sputtering layer is nickel-chromium alloy, and the target of the second sputtering layer is pure chromium.

Step 605: spraying transparent powder. Transparent powder is sprayed onto the metal coating layer to form a transparent powder layer; specifically, the curing temperature of the transparent powder layer is 177° C. and the curing time is 15-20 minutes; specifically, the transparent powder layer is made of acrylic resin, has excellent aging resistance, does not change color after long-term use, does not reduce the adhesion of the coating, and can bond well with the metal coating layer, so as to effectively protect the metal coating layer from being damaged during use, and prolong the service life of the metal coating layer. After the transparent powder layer is cured, the whole surface treatment process is completed.

Specifically, the equipment used in the preparation method is a high-vacuum magnetron sputtering coating machine.

### Example 7

The process flow of this Example is the same as that of Example 1 except for some parameters in the step of plasma treatment. Only the difference from Example 1 will be introduced below, and the flow diagram will not be shown separately.

In this Example, the gas introduced into the cavity is hydrogen with a flow rate of 300 sccm, and the other parameters are the same as those in Example 1.

### Example 8

The process flow of this Example is the same as that of Example 1 except for some parameters in the step of plasma treatment. Only the differences from Example 1 will be introduced below, and the flow diagram will not be shown separately.

In this Example, the gas introduced into the cavity is argon with a flow rate of 400 sccm, and the working power of the plate electrodes in the plasma equipment is 1.2 kW. The other parameters are the same as those in Example 1.

### Example 9

The process flow of this Example is the same as that of Example 1 except for some parameters in the step of plasma treatment. Only the differences from Example 1 will be introduced below, and the flow diagram will not be shown separately.

In this Example, the gas introduced into the cavity is nitrogen with a flow rate of 400 sccm, and the working time of the plate electrodes in the plasma equipment is 20 s. The other parameters are the same as those in Example 1.

### Example 10

The process flow of this Example is the same as that of Example 1 except that plasma treatment is not performed. Only the difference from Example 1 will be introduced below, and the flow diagram will not be shown separately.

Step 603B: heat treatment. After the high-gloss organic medium layer is cured, the aluminum alloy wheel hub is heated. The aluminum alloy wheel hub is put into an oven for heating, in which the temperature of the oven is set to 170° C., and the heating time is 10 minutes; and after the wheel hub is taken out of the oven after being heated, the surface temperature of the wheel hub can reach 130° C. By replacing plasma treatment with heating, though not as good as plasma treatment, the effect of heating is still greatly superior to the related art by using the structural design of the surface protective layer in the above-mentioned Examples 1-5.

In this Example, step 603B is used to replace step 603.

In order to verify the effect of the structure and preparation method in the Examples of the present disclosure, the aluminum alloy wheel hubs treated in the above-mentioned Examples 6-10 were tested and compared. Detailed test items and data are shown in Table 1.

TABLE 1

| Examples | Example 6 | Example 7 | Example 8 | Example 9 | Example 10 |
|---|---|---|---|---|---|
| crosscut | 100% no | 99% no | 98% no | 99% no | 96% no |
| adhesion | falloff | falloff | falloff | falloff | falloff |
| CASS | 1.0 mm | 1.0 mm | 1. mm | 1.0 mm | 0.9 mm |
| FLIFORM | 2. mm | 2.2 mm | 2. mm | 2.4 mm | 2.3 mm |
| water | no change, | no change, | no change, | no change, | no change, |
| resistance | adhesion | adhesion | adhesion | adhesion | adhesion |
| test | 100% | 98% | 85% | 94% | 90% |

In the table, CASS is short for Copper-Accelerated Acetic Acid Salt Spray test, and FLIFORM is short for high temperature and humidity test.

The experiment proves that the effect of Example 6 is the best, meanwhile, the effects of other Examples are greatly superior to the related art too. In general, the requirement for crosscut adhesion is 90% no falloff, of course, there are some manufacturers with slightly higher requirements. The water resistance test requires an adhesion of 80% or more.

The above is only specific description of Examples of the present disclosure, and is not intended to limit the scope of protection of the present disclosure. Any other equivalent transformation should fall within the scope of protection of the present disclosure.

1. A metal surface protective layer, comprising an organic medium layer, a metal coating layer and a transparent powder layer from inside to outside,
wherein the organic medium layer is formed by spraying organic medium powder onto a surface of metal to be treated,
the metal coating layer is formed by performing magnetron sputtering PVD plating on the organic medium layer,
the organic medium layer is subjected to surface activation and cleaning treatment before the magnetron sputtering PVD plating, and
the transparent powder layer is formed by spraying transparent powder onto the metal coating layer.

2. The metal surface protective layer according to claim 1, wherein the surface activation and cleaning treatment is plasma treatment.

3. The metal surface protective layer according to claim 2, wherein the metal surface protective layer further comprises a passivation layer,
the passivation layer is formed by performing zirconium-titanium pretreatment on a substrate surface of the metal to be treated, and
the passivation layer is between the substrate surface of the metal to be treated and the organic medium layer.

4. The metal surface protective layer according to claim 3, wherein the organic medium layer is made of epoxy resin,
the metal coating layer comprises a first sputtering layer with a target of nickel-chromium alloy and a second sputtering layer with a target of pure chromium, and the transparent powder layer is made of acrylic resin.

5. The metal surface protective layer according to claim 2, wherein a thickness of the metal coating layer is 0.08-0.1 μm,
a thickness of the organic medium layer is 120-150 μm, and
a thickness of the transparent powder layer is 80-120 μm.

6. A preparation method of the metal surface protective layer according to claim 1, comprising:
spraying an organic medium material onto a surface of metal to be treated to form an organic medium layer;
performing surface activation and cleaning treatment on the organic medium layer to improve activity and cleanliness of a surface of the organic medium layer;
performing magnetron sputtering PVD plating on the organic medium layer subjected to surface activation and cleaning treatment to form a metal coating layer; and
spraying transparent powder onto the metal coating layer to form a transparent powder layer.

7. The method according to claim 6, wherein the step of performing surface activation and cleaning treatment on the organic medium layer to improve activity and cleanliness of the surface of the organic medium layer comprises:
performing surface plasma treatment on the organic medium layer.

8. The method according to claim 6, wherein before spraying the organic medium material onto the surface of the metal to be treated to form the organic medium layer, the method further comprises:
performing zirconium-titanium pretreatment on a substrate surface of the metal to be treated to form a passivation layer.

9. The method according to claim 6, wherein the step of performing magnetron sputtering PVD plating on the organic medium layer subjected to surface activation and cleaning treatment to form the metal coating layer comprises:
performing magnetron sputtering PVD plating on the organic medium layer by taking nickel-chromium alloy as a target, to form a first sputtering layer; and
performing magnetron sputtering PVD plating on the first sputtering layer by taking pure chromium as a target, to form a second sputtering layer.

10. The method according to claim 7, wherein in the step of performing surface plasma treatment on the organic medium layer, a plate electrode for plasma treatment is made of aluminum alloy, oxygen serves as gas, a working pressure of the gas is 0.003-0.008 torr, and a working power of a device for plasma treatment is 1.2-1.5 kW.
